(19) United States
(12) Patent Application Publication
(10) Pub. No.: US 2016/0301375 A1
(43) Pub. Date: Oct. 13, 2016

(54) Utune acoustics

(71) Applicant: Justin L. Watts, Las Vegas, NV (US)

(72) Inventor: Justin L. Watts, Las Vegas, NV (US)

(21) Appl. No.: 14/683,963

(22) Filed: Apr. 10, 2015

(51) Int. Cl. H03G 3/32; H04R 29/00

(52) U.S. Cl. CPC H03G 3/32; H04R 29/00

(57) ABSTRACT

An assembly and method for automatic real time enhancement of audio signal on the basis of listening environment and ambience noise, wherein said assembly comprises one or more audio sensing device such as microphone, a computer implemented system further comprising a non-transitory computer-readable storage medium storing instructions and components to analyze and process audio signals; and a method to capture the sound in listening environment using the audio sensors whereby plurality of audio sensors are located at plurality of locations to capture the proximal sound signals and transferring the captured signal to a system, whereby, the instructions stored in memory on execution by the computer analyze and process the sound signals to provide enhanced sound signal which are transferred to plurality of speakers.

### CROSS REFERENCE TO RELATED APPLICATION

Not Applicable

### FEDERALLY SPONSORED RESEARCH AND DEVELOPMENT

Not Applicable

### MICROFICHE APPENDIX

Not Applicable

### BACKGROUND OF THE INVENTION

(1) Field of Invention

The present invention generally relates to audio signal processing. More specifically, the present invention relates to a system and method for adjusting the audio level on the basis of the listening environment.

(2) Background of Invention

In recent years, many developments have been made in field of audio technologies. Most of the efforts have attempted to provide a better and personalized sound experience to the users. Such attempts include audio signal processing, improved speaker designs, and customizing the listening environment. Such attempts have been incorporated in almost all electronic entertainment devices, such as music systems, theaters, headphones, etc. One of the most significant advancements in recent time is the development of surround system, which uses a plurality of speakers to provide a realistic sound experience. Such surround systems have become quite popular, and are available in movie theaters, home entertainment systems, headphones, etc.

The user typically adjusts different audio controls, such as volume, bass, treble, etc. according to his requirement. However, the audio is played in different environments, which may vary from silent to noisy. Noisy environments may impair listening pleasure, and the user is forced to adjust the volume of audio and other settings. For example, background noises, such as noise from the air conditioning or some other activity in room, may cause the user to increase the volume of audio and decrease the same when the noise decreases, such as stopping the air conditioning.

A user travelling in a vehicle may often require frequent adjustment of sound level, as the noise level in the vehicle varies continuously depending upon speed of car, external traffic, etc. Also, it frequently occurs that one soundtrack is louder than others, which causes inconvenience to the user.

People generally use headphones when present in a group of people, so that they can listen conveniently without disturbing others. Sounds created by neighboring people may impair listening pleasure to the user, and often requires increasing the sound level to overcome ambient noises. However, when the ambient noises stops or decreases, the volume level of headphone appears high. The user has to continuously adjust the volume for comfortable listening. Thus, there is a need for system to automatically adjust the volume depending on the ambient noise level.

Providing a proper listening environment in public places for entertainment, such as a movie theatre, is often a difficult task. Most of the theatres use advance sound systems for an enhanced viewer experience. Adjusting the proper sound settings is a challenging task, as ambient noise of the hall varies depending on the amount of people occupying the hall. Also, the ambience noise may vary in different areas of the hail, as a group of people may be talking, eating, or any other activity creating noises. Thus, it is very difficult to provide a uniform listening environment to all of the individuals occupying the hall. Any change in volume level may significantly affect overall sound quality. Moreover, for some people, the sound could be too high, while, for others, it may be too low. Thus, there is need for a system that could provide a more personal sound experience in public entertainment places.

Prior art discloses number of techniques for automatically adjusting the sound level depending on ambient noise. One such technique is disclosed in U.S. Pat. No. 5,434,922, entitled “Method and Apparatus for Dynamic Sound Optimization,” which discloses a system that is comprised of a microphone to capture the sound signals in the area proximal to microphone, whereby the total signal (i.e., including the desired signal and noise) is analyzed to detect the noise component. The noise signal is used for audio processing, whereby the extracted noise component is compared with the original signal from the audio source, and the result is then used in a subsequent amplification-calculation stage. The analysis is used to automatically adjust the audio volume of the acoustic signal output to the listener.

Most of the techniques rely on a similar principle, i.e. sensing the ambience noise levels and automatically adjusting the volume of audio signal to overcome the noises. The techniques mostly differ in approaches towards analyzing the noise component from the signal captured by the sound sensor. For example, U.S. Pat. No. 6,628,788 B2, entitled “Apparatus and method for noise-dependent adaptation of an acoustic useful signal,” discloses a system that extracts useful sound signals from the total signal captured by the sensor.

Another, U.S. Pat. No. 6,766,025, entitled “intelligent speaker training using microphone feedback and pre-loaded templates,” discloses a programmable speaker that uses instructions stored in the memory of the speaker and digital signal processing (DSP) to digitally perform transform functions on input audio signals to compensate for speaker related distortion and listening environment distortion. Tuning the speaker is performed by applying a reference signal and a control signal to the input of the programmable speaker.

Another, U.S. Patent Appl. No. 20140010377, entitled “Electronic device and method of adjusting volume in teleconference,” discloses a system for automatic sound adjustment technique during teleconference. The sensor on the device adjusts the speaker volume, and the input from the receiver adjusts the incoming audio signal.

Another prior art, U.S. Pat. No. 6,771,769, entitled “Method and apparatus for active reduction of speakerphone singing,” discloses a system for the identification of signals (i.e., voice input or speaker output) in the speakers of communication devices for reducing acoustic feedback. The method involves inserting a signature noise (i.e., an identification mark) to output signals radiated by the speaker which enable these signals to be separated from speech input to the microphone. The result of the analysis is used to reduce the probability of singing.

The known techniques suffer from one or more disadvantages. One problem in particular is the disorder of overall sound by amplifying one or more components of the sound signal. To the best of our knowledge, no prior art discuses enhancing overall sound experience in bigger listening areas, such as movie halls, or optimizing individual sound experience in such big listening areas depending on ambient noise within the listening area.

Thus, there is a need for a technique to overcome the problems of the prior art, and to provide improved sound experience in bigger listening environments while also optimizing individual listening environment.

### SUMMARY OF THE INVENTION

The present invention, therefore, has as its principal objective to provide an assembly and method for automatic and real time enhancement of audio signal depending on the listening environment and ambience noise for an improved sound experience.

Another objective of the invention is to fulfill the foregoing object by providing an improved method for audio enhancement.

Yet another objective of the current invention is to provide an economic and versatile apparatus that is easy to install and use.

Certain embodiments of the current invention provide an assembly and method for automatic and real time enhancement of audio signal on the basis of listening environment and ambience noise. Said assembly is comprised of one or more audio sensing devices, such as a microphone, a computer implemented system that includes a non-transitory, computer-readable storage medium for storing instructions and components to analyze and process audio signals, and a method to capture the sound in listening environment using the audio sensors. Pluralities of audio sensors are located at a plurality of locations to capture the proximal sound signals and transfer the captured signal to a system. After this, the instructions that are stored in the memory, on execution by the computer, analyze and process the sound signals to provide enhanced sound signals, which are then transferred to a plurality of speakers. Moreover, the method includes an input step, whereby a user provides the type of listening environment from predefined templates, and the whole process is continuously repeated to provide real time audio enhancement.

According to another embodiment of current invention, the computer implemented system that is comprised of stored instructions could be programed to recognize the configuration and location of sensors and speakers.

According to another embodiment of current invention, the computer implemented system that is comprised of stored instructions could be programed to process individual audio signals for an overall richer sound experience.

According to another embodiment of current invention, the computer implemented system contains one or more audio inputs and outputs, for one or more speakers.

According to another embodiment of current invention, the computer implemented system is comprised of controls for user input, such as volume, bass etc. and components for sound processing, including amplification, whereby such controls and components are obvious to a person skilled in the art.

In addition to the various objectives and advantages of the present invention, described with some degree of specificity above, it should be obvious that additional objectives and advantages of the present invention will become more readily apparent to those persons who are skilled in the relevant art from the following, more detailed description of the invention.

### DETAIL DESCRIPTION OF THE INVENTION

Before explaining at least one embodiment of the invention in detail, it is to be understood that the invention is not limited in its application to the details of construction and the arrangements of the components set forth in the following description. The invention is capable of other embodiments, and of being practiced and carried out in various ways. Also, it is to be understood that the phraseology and terminology employed herein are for the purpose of description, and should not be regarded as limiting.

The present invention provides a programmable system for enhancing sound experience based on the listening environment and ambience noise levels according to set of instruction stored in system memory. A soundtrack may sound different in small room as compared to a larger room. A user typically adjusts various components of the sound to improve the audio experience. The present invention provides an automatic method based on set of instructions that are programmed into computer-implemented system for enhancing the audio signal according to the listening environment.

The present invention provides an assembly that is comprised of audio sensors, such as microphones or any other device known obvious to a person skilled in the art, for sensing surrounding sounds and inputting the same to another device. The sensing device may optionally convert analogue signals to digital signals. The invention may use more than one sound sensor, depending on the size of the listening area. For example, in a small room, one sensor would be sufficient; however, a bigger place, such as a hall, may require more than one sensor. Preferably, the hall may be divided into zones, such as each zone would have a different listening environment depending upon distance form speakers and ambient noise. Each of the zones will have its own sensor that will help to provide an optimal sound experience to all individuals in the listening area

The input from the sensors is fed to a computer-implemented system through a conducting medium, or wirelessly through Bluetooth, Wi-Fi, or the like. The system also has input for audio signal, and outputs for the speakers. The system is further comprised of hardware for sound processing, such as a sound card or any other device obvious for person skilled in the art, for audio customization, a software stored in the memory of system that, on command by the processor, allows analysis of input audio signals including those from sensor and process them according to the set of instruction stored in the memory of system. The system could be programmed by the user providing information, such as the type of listening environment or configuration and location of the speakers and the sensors in the listening area. The system provides advance controls for the user to adjust various audio settings, such as bass, treble etc. or use the default templates stored in the memory. Based on the input settings, the software processes the audio signal based on the listening environment and ambience noise levels. Thus, the current system not only adjusts the volume level, but also enhances the overall sound experience. Moreover, the software analyses each sensor signal to determine the listening environment in a proximal area of sensor, and provides adjustment for optimum sound experience. Thus, different speakers are individually calibrated to provide overall richer sound throughout the listening area.

The invention is particularly useful in entertainment theatres, where a good number of speakers are used to provide uniform surround experience to the users. The present invention could provide better individual sound experience by sensing the sound levels, including noise in different areas of the hall, and calibrating individual signals to various speakers. For example, the volume of speakers near a noisy group could be selectively adjusted. Similarly, in headphones, the noise levels at both earpieces could be sensed separately, and then enhanced accordingly to provide a richer sound experience. Also, in the vehicle, the present invention could provide automatic and better audio. Typically, a vehicle has two or more speakers, whereby the music system in the vehicle allows adjusting the setting of each speaker. However, it is often difficult for the user to properly adjust the settings, as the user could not know the sound level of rear area. Installing sensors in the front and rear of the vehicle could provide input to the system, including the level of ambient noises, and the software automatically adjusts the individual speaker settings, thus providing comfort and a richer sound experience to all the people in the vehicle. Moreover, the process is continuously repeated, including getting input from sensor and optimizing audio signals, providing real time sound calibrations and, thus, optimum sound.

Those skilled in the art should appreciate that they can readily use the disclosed conception and specific embodiment as a basis for designing or modifying other structures for carrying out the same purposes of the present invention, and that such other structures do not depart from the spirit and scope of the invention in its broadest form.

1. An assembly for audio enhancement based on the listening environment and ambient noise level comprising:
a. A plurality of audio sensors to capture sound in listening area;
b. A computer implemented system for analyzing and processing audio signals.

2. The assembly according to claim 1, wherein said sensor is a microphone.

3. The assembly according to claim 1, wherein said computer implemented system further comprises:
a. Input for original audio signal;
b. Plurality of inputs for plurality sensors
c. Plurality of outputs for plurality of speakers;
d. Means for sound processing, such as but not limited to, a sound card.
e. A non-transitory computer-readable storage medium storing set of instructions.

4. The assembly according to claim 1, wherein said sound sensor transmits signals to said system through wireless means, such as Bluetooth or Wi-Fi, or through conducting means, such as electrical wire.

5. A non-transitory, computer-readable storage medium storing a set of instructions programmed by the user that, when executed by a computer-implemented system, cause the system to perform a method for using sound sensor(s) to enhance the audio output based on listening environment and ambient noise level, said method comprising:
a. Capturing ambient sound signals using plurality of sound sensors;
b. Analyzing different components of captured sound signals, including noises, and comparing that to audio signal from playing source; and
c. Using the result of analysis to process each of the output signals for optimizing overall sound experience.

6. A non-transitory computer-readable storage medium storing set of instructions according to claim 5, wherein said programming comprise, providing type of listening environment, configuration and location of speakers, configuration and location of sensors, and if any audio settings desired by the user.

7. A method for audio enhancement based upon listening environment and ambience noises, wherein said method comprises:
a. Capturing ambient sound signals from different parts of the listening area using plurality of sensors;
b. Analyzing the different components of captured sound signals including ambient noises and comparing to original audio signal from playing source; and
c. Using the result of analysis to process each of the output signals for optimizing overall sound experience.

8. A method according to claim 7, whereby the optimization of individual speaker settings depends on input provided by the microphone in proximity to the speaker.
